(19) United States
(12) Patent Application Publication
(10) Pub. No.: US 2025/0244383 A1
(43) Pub. Date: Jul. 31, 2025

(54) CHIP INSPECTION DEVICE AND CHIP INSPECTION METHOD

(71) Applicant: AUO Corporation, Hsinchu City (TW)

(72) Inventors: Cheng-Kai KAO, Hsinchu City (TW); Fu-Cheng WEI, Hsinchu City (TW)

(21) Appl. No.: 18/915,502

(22) Filed: Oct. 15, 2024

(30) Foreign Application Priority Data
Jan. 25, 2024 (TW) 113102990

(51) Int. Cl. G01R 31/317

(52) U.S. Cl. CPC G01R 31/31717

(57) ABSTRACT

A chip inspection device comprises a first chip, a second chip, and a processor. During an initial period, the processor outputs a passing down signal to the first chip. During an inspection period, the first chip outputs an error data signal to the processor according to a data signal and outputs an error passing down signal to the second chip according to the passing down signal, and the second chip receives the error passing down signal and outputs the error data signal to the processor. During a calibration period, the processor outputs a feedback signal to the second chip according to the error data signal of the first chip and writes the data signal to the second chip, and the second chip receives the feedback signal and the data signal and outputs the feedback signal or the passing down signal according to the feedback signal.

### RELATED APPLICATIONS

This application claims priority to Taiwan Application Serial Number 113102990, filed on Jan. 25, 2024, which is herein incorporated by reference in its entirety.

### BACKGROUND

### Technical Field

The present disclosure relates to an inspection device and an inspection method. More particularly, the present disclosure relates to a chip inspection device and a chip inspection method.

### Description of Related Art

At present, the micro IC data transmission architecture of a panel may cause the entire row of micro ICs a data transmission failure due to the breakage of the wires transmitting passing down signals (chip select signals) or the failure of the microchip itself. Therefore, how to design to solve the above problems is an important issue in this field.

### SUMMARY

This summary is intended to provide a simplified summary of the present disclosure, so as to make the readers have a basic understanding of the present disclosure. This summary is not an extensive overview of the present disclosure, and it is not intended to identify key/critical elements of the embodiments or to delineate the scope of the present disclosure.

One technical aspect of the present disclosure relates to a chip inspection device. The chip inspection device comprises a first chip, a second chip and a processor. The second chip is coupled to the first chip. The processor is coupled to the first chip and the second chip. During an initial period, the processor sequentially writes a data signal to the first chip and the second chip to perform inspection. During the initial period, the processor outputs a passing down signal to the first chip. During an inspection period, the first chip outputs an error data signal to the processor according to the data signal. During the inspection period, the first chip outputs an error passing down signal to the second chip according to the passing down signal. During the inspection period, the second chip receives the error passing down signal and outputs the error data signal to the processor. During a calibration period, the processor outputs a feedback signal to the second chip according to the error data signal of the first chip, and the processor writes the data signal to the second chip. During the calibration period, the second chip receives the feedback signal and the data signal, and the second chip outputs the feedback signal or the passing down signal according to the feedback signal. The inspection period is after the initial period, and the calibration period is after the inspection period.

Another technical aspect of the present disclosure relates to a chip inspection method. The chip inspection method comprises the following steps: during an initial period, writing a data signal to the a chip and a second chip sequentially by a processor to perform inspection; during the initial period, outputting a passing down signal to the first chip by the processor; during an inspection period, outputting an error data signal to the processor by the first chip according to the data signal; during the inspection period, outputting an error passing down signal to the second chip by the first chip according to the passing down signal; during the inspection period, receiving the error passing down signal and outputting the error data signal to the processor by the second chip; during a calibration period, outputting a feedback signal to the second chip by the processor according to the error data signal of the first chip, and writing the data signal to the second chip by the processor; and during the calibration period, receiving the feedback signal and the data signal by the second chip, and outputting the feedback signal by the second chip according to the feedback signal.

Yet another technical aspect of the present disclosure relates to a chip inspection device. The chip inspection device comprises a first chip, a second chip and a processor. The second chip is coupled to the first chip. The processor is coupled to the first chip and the second chip. During an initial period, the processor sequentially writes a data signal to the first chip and the second chip to perform inspection. During an inspection period, the first chip outputs an error data signal to the processor according to the data signal. During a calibration period, the processor outputs a feedback signal to the second chip according to the error data signal of the first chip, and the processor writes the data signal to the second chip. During the calibration period, the second chip receives the feedback signal and the data signal, and the second chip outputs according to the feedback signal. The inspection period is after the initial period, and the calibration period is after the inspection period.

Therefore, based on the technical content of the present disclosure, the chip inspection device and the chip inspection method shown in the embodiments of the present disclosure can use a processor to output feedback signals to the chip, so as to achieve the effect of normal operation of the chip.

After referring to the following detailed description, those skilled in the art can easily understand the basic spirit and other purposes of the present disclosure, as well as the technical means and implementation aspects adopted in the present disclosure.

### BRIEF DESCRIPTION OF THE DRAWINGS

The present disclosure can be more fully understood by reading the following detailed description of the embodiment, with reference made to the accompanying drawings as follows.

FIG. 1 is a block schematic diagram of a chip inspection device in accordance with an embodiment of the present disclosure.

FIG. 2 is a time diagram of a plurality of signals of a chip inspection device in accordance with an embodiment of the present disclosure.

FIG. 3 is a time diagram of a plurality of signals of a chip inspection device in accordance with an embodiment of the present disclosure.

FIG. 4 is a time diagram of a plurality of signals of a chip inspection device in accordance with an embodiment of the present disclosure.

FIG. 5 is a use scenario diagram of a plurality of signals of a chip inspection device in accordance with an embodiment of the present disclosure.

FIG. 6 is a use scenario diagram of a plurality of signals of a chip inspection device in accordance with an embodiment of the present disclosure.

FIG. 7A is a flowchart of a chip inspection method in accordance with an embodiment of the present disclosure.

FIG. 7B is a flowchart of a chip inspection method in accordance with an embodiment of the present disclosure.

In accordance with common practice, the various features and components in the figures are not shown to scale, but are shown in the way that best presents the specific features and components relevant to the present disclosure. In addition, the same or similar reference symbols are used to refer to similar elements/components in different figures.

### DETAILED DESCRIPTION

In order to make the description of the present disclosure more detailed and complete, the following provides an illustrative description of the implementation aspects and specific embodiments of the present disclosure; but this is not the only form of implementing or using the specific embodiments of the present disclosure. The embodiments cover the features of a plurality of specific embodiments as well as steps and their sequences for constructing and operating these specific embodiments. However, other specific embodiments may also be used to achieve the same or equivalent functions and step sequences.

Unless the present disclosure defines otherwise, the meanings of scientific and technical terms used herein are the same as those commonly understood and customary by those of ordinary skill in the art. In addition, without conflicting with the context, the singular terms used herein include plural referents; while the plural terms used herein also include singular referents.

Furthermore, the term “couple” or “connect” used in the present disclosure may refer to two or more components being in direct physical or electrical contact with each other, or being in indirect physical or electrical contact with each other, or it may also refer to two or more components operating or acting on each other.

In the present disclosure, the term “ . . . er” or “ . . . or” (e.g., processor) generally refers to an object that is connected in a certain manner by one or more transistors and/or one or more active/passive components to process signals.

Certain terms are used in the specification and the claims to refer to specific components. However, those of ordinary skill in the art would understand that the same components may be referred to by different terms. The specification and claims do not use the differences in terms as a way to distinguish components, but the differences in functions of the components are used as a basis for distinguishing. The term “comprising” used in the specification and claims is open-ended, that is, including but not limited to.

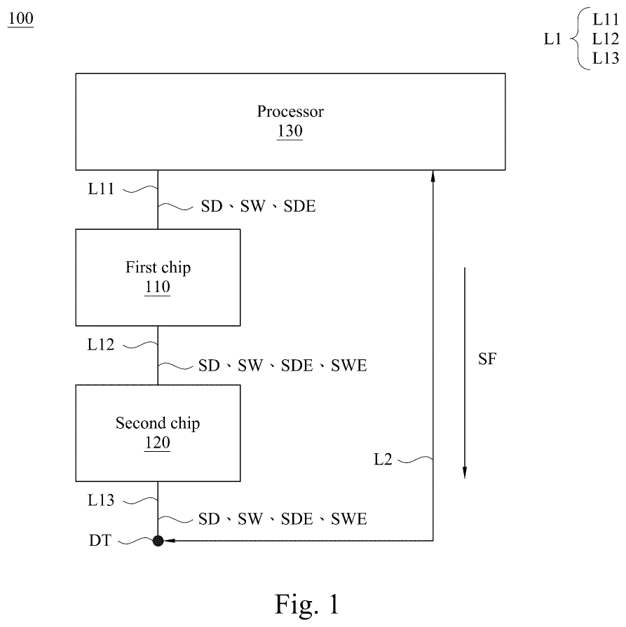

FIG. 1 is a block schematic diagram of a chip inspection device in accordance with an embodiment of the present disclosure. As shown in FIG. 1, in an embodiment, the chip inspection device 100 comprises a first chip 110, a second chip 120 and a processor 130. Regarding the connection relationship, the second chip 120 is coupled to the first chip 110, and the processor 130 is coupled to the first chip 110 and the second chip 120.

For example, the first chip 110 and/or the second chip 120 may be a micro chip or a micro integrated circuit (micro IC), and the processor 130 may be a timing controller, but the present disclosure is not limited thereto.

In addition, the micro IC may thin the IC to about 100 microns (μm) level and serve as a controller, and the micro IC may drive a group (or multiple groups) of red, green and/or blue micro light-emitting diodes (R/G/B micro LEDs), but the present disclosure is not limited thereto.

In some embodiments, the processor 130 may be a single processor or an integrated device of multiple microprocessors, such as a central processing unit (CPU), a graphics processing unit (GPU) or an application-specific integrated circuit (ASIC), etc., but the present disclosure is not limited thereto.

In an embodiment, the chip inspection device 100 further comprises a first wire L1, a second wire L2 and a node DT. The first wire L1 comprises sub-wires L11, L12 and L13. Regarding the connection relationship, the sub-wire L11 is coupled to the processor 130 and the first chip 110, the sub-wire L12 is coupled to the first chip 110 and the second chip 120, the sub-wire L13 is coupled to the second chip 120 and the node DT, and the node DT is coupled to the processor 130.

In an embodiment, the processor 130 is coupled to the first chip 110 through the first wire L1. The first chip 110 is coupled to the second chip 120 through the first wire L1. The second chip 120 is coupled to the node DT through the first wire L1. The first wire L1 is configured to transmit a passing down signal SW. The node DT is coupled to the processor 130 through the second wire L2. The second wire L2 is configured to transmit a feedback signal SF.

For example, the passing down signal SW may be a chip select signal, and the feedback signal SF may be a chip select signal, but the present disclosure is not limited thereto.

In some embodiments, the passing down signal SW may be the same as the feedback signal SF. In some embodiments, the passing down signal SW may be different from the feedback signal SF.

In some embodiments, the processor 130 may output a data signal SD, the passing down signal SW, a data clock signal SDC and/or a pulse clock signal SPC. In some embodiments, the first wire L1 may transmit the data signal SD, the passing down signal SW, the data clock signal SDC and/or the pulse clock signal SPC.

For example, the data signal SD may be a data signal generally written to a light-emitting diode driving circuit, such as a red, green or blue signal of 0 to 256 gray levels, the passing down signal SW may be any signal written to a micro chip, the data clock signal SDC may be any data clock signal used to drive a micro chip or a light-emitting diode driving circuit, and the pulse clock signal SPC may be any pulse-width modulation clock signal used to drive a micro chip or a light-emitting diode driving circuit, but the present disclosure is not limited thereto.

In some embodiments, the first chip 110 may be coupled to one or more pixels, and the second chip 120 may be coupled to one or more pixels, but the present disclosure is not limited thereto.

In some embodiments, the first chip 110 may output an error passing down signal SWE. In some embodiments, the first chip 110 may output an error data signal SDE. In some embodiments, the second chip 120 may output the error passing down signal SWE. In some embodiments, the second chip 120 may output the error data signal SDE.

In some embodiments, the passing down signal SW and the error passing down signal SWE are signals different from each other. In some embodiments, the data signal SD and the error data signal SDE are signals different from each other. In some embodiments, the passing down signal SW, the error passing down signal SWE, the data signal SD and the error data signal SDE are signals different from each other.

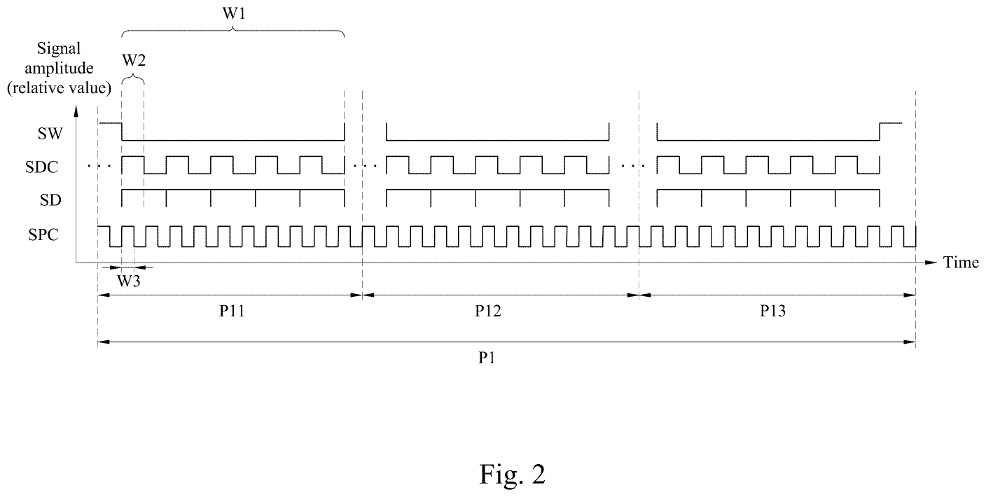

FIG. 2 is a time diagram of a plurality of signals of a chip inspection device in accordance with an embodiment of the present disclosure. As shown in FIG. 2, in some embodiments, the time diagram comprises the passing down signal SW, the data clock signal SDC, the data signal SD, the pulse clock signal SPC and a period P1. The period P1 comprises sub-periods P11, P12 and P13.

In some embodiments, the passing down signal SW in the sub-period P11, the passing down signal SW in the sub-period P12 and the passing down signal SW in the sub-period P13 each have a pulse length W1.

For example, the passing down signal SW in the sub-period P11, the passing down signal SW in the sub-period P12 and the passing down signal SW in the sub-period P13 each have a high-level signal and a low-level signal, and the pulse length W1 may be the time length of the abovementioned low-level signal, but the present disclosure is not limited thereto.

In some embodiments, the data clock signal SDC in the sub-period P11, the data clock signal SDC in the sub-period P12 and the data clock signal SDC in the sub-period P13 each have a pulse length W2.

For example, the data clock signal SDC in the sub-period P11, the data clock signal SDC in the sub-period P12 and the data clock signal SDC in the sub-period P13 each have a high-level signal and a low-level signal, and the pulse length W2 may be the time length of the abovementioned high-level signal, but the present disclosure is not limited thereto.

In addition, the pulse length W2 may also be the time length of the abovementioned low-level signal, but the present disclosure is not limited thereto.

In some embodiments, the pulse clock signal SPC in the sub-period P11, the pulse clock signal SPC in the sub-period P12 and the pulse clock signal SPC in the sub-period P13 each have a pulse length W3.

For example, the pulse clock signal SPC in the sub-period P11, the pulse clock signal SPC in the sub-period P12 and the pulse clock signal SPC in the sub-period P13 each have a high-level signal and a low-level signal, and the pulse length W3 may be the time length of the abovementioned high-level signal, but the present disclosure is not limited thereto.

In addition, the pulse length W3 may also be the time length of the abovementioned low-level signal, but the present disclosure is not limited thereto.

In some embodiments, the pulse length W1 may be greater than the pulse length W2. In some embodiments, the pulse length W1 may be equal to the pulse length W2. In some embodiments, the pulse length W1 may be greater than the pulse length W2 and the pulse length W3. In some embodiments, the pulse length W1 may be equal to the pulse length W2 and the pulse length W3. In some embodiments, the pulse length W2 may be greater than the pulse length W3.

For example, the pulse length W1 may be approximately 10 times the pulse length W2, and the pulse length W2 may be approximately 0.5 times the pulse length W3, but the present disclosure is not limited thereto.

Please refer to FIG. 1 and FIG. 2 together. In some embodiments, the period P1 may be a period during which the processor 130 enters a chip scanning mode upon being initially booted and sequentially transmits inspection data signals to each chip.

For example, the processor 130 may have a scanning algorithm to perform the chip scanning mode, and the processor 130 may sequentially transmits the data signal SD to the first chip 110 and the second chip 120.

Furthermore, the sub-period P12 may be a sub-period during which the data signal SD is written to the first chip 110, and the sub-period P13 may be a sub-period during which the data signal SD is written to the second chip 120, but the present disclosure is not limited thereto.

In some embodiments, during the sub-period P12, the first chip 110 may receive the passing down signal SW and output the passing down signal SW to the second chip 120. During the sub-period P13, the second chip 120 may receive the passing down signal SW and output the passing down signal SW.

In some embodiments, the sub-period P12 is after the sub-period P11, and the sub-period P13 is after the sub-period P12. In some embodiments, the length of the sub-period P12 is the same as the length of the sub-period P11, and the length of the sub-period P13 is the same as the length of the sub-period P12. In some embodiments, the length of the sub-period P12 is different from the length of the sub-period P11. In some embodiments, the length of the sub-period P13 is different from the length of the sub-period P12.

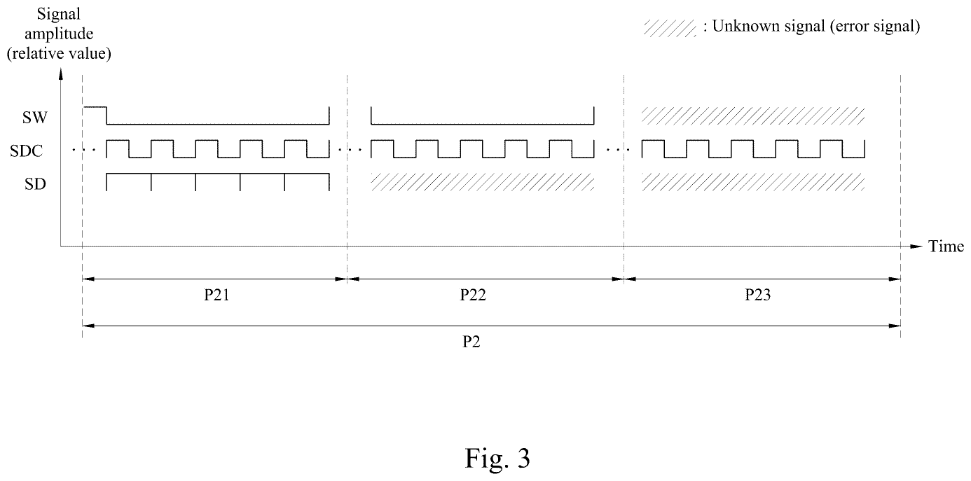

FIG. 3 is a time diagram of a plurality of signals of a chip inspection device in accordance with an embodiment of the present disclosure. As shown in FIG. 3, in some embodiments, the time diagram comprises the passing down signal SW, the data clock signal SDC, the data signal SD, a plurality of unknown signals and a period P2. The period P2 comprises sub-periods P21, P22 and P23.

For example, each of the plurality of unknown signals may be the error data signal SDE and/or the error passing down signal SWE, but the present disclosure is not limited thereto. In some embodiments, the passing down signal SW in the sub-period P21 and the passing down signal SW in the sub-period P22 each have a pulse length W1.

For example, the passing down signal SW in the sub-period P21 and the passing down signal SW in the sub-period P22 each have a high-level signal and a low-level signal, and the pulse length W1 may be the time length of the abovementioned low-level signal, but the present disclosure is not limited thereto.

In some embodiments, the data clock signal SDC in the sub-period P21, the data clock signal SDC in the sub-period P22 and the data clock signal SDC in the sub-period P23 each have a pulse length W2.

For example, the data clock signal SDC in the sub-period P21, the data clock signal SDC in the sub-period P22 and the data clock signal SDC in the sub-period P23 each have a high-level signal and a low-level signal, and the pulse length W2 may be the time length of the abovementioned high-level signal, but the present disclosure is not limited thereto.

In addition, the pulse length W2 may also be the time length of the abovementioned low-level signal, but the present disclosure is not limited thereto.

Please refer to FIG. 1 and FIG. 3 together. In some embodiments, during the period P2, each chip of the chip inspection device 100 may change from an input mode to an output mode, each chip may input the data signal SD to the processor 130, and the processor 130 may sequentially receive the data signals SD of each chip.

For example, during the sub-period P22, when the first chip 110 fails, the data signal SD output by the first chip 110 may be the error data signal SDE, the passing down signal SW output by the first chip 110 may be the error passing down signal SWE, the first chip 110 outputs the error data signal SDE to the second chip 120, and the first chip 110 outputs the error passing down signal SWE to the processor 130. During the sub-period P23, the second chip 120 receives the error passing down signal SWE, and the second chip 120 outputs the error data signal SDE to the processor 130, but the present disclosure is not limited thereto.

Furthermore, the processor 130 may sequentially receive and inspect the error passing down signal SWE of the first chip 110 and the error passing down signal SWE of the second chip 120.

In some embodiments, the processor 130 may determine which chip fails based on the order in which the error passing down signals SWE of each chip are received.

For example, the processor 130 receives the error passing down signal SWE of the first chip 110 first, and then receives the error passing down signal SWE of the second chip 120. Therefore, the processor 130 may determine that the first chip 110 fails, or the processor 130 may determine that the wire between the first chip 110 and the second chip 120 is disconnected, but the present disclosure is not limited thereto.

In some embodiments, the sub-period P22 is after the sub-period P21, and the sub-period P23 is after the sub-period P22. In some embodiments, the length of the sub-period P22 is the same as the length of the sub-period P21, and the length of the sub-period P23 is the same as the length of the sub-period P22. In some embodiments, the length of the sub-period P22 is different from the length of the sub-period P21. In some embodiments, the length of the sub-period P23 is different from the length of the sub-period P22.

In some embodiments, the frequency or voltage of the error data signal SDE is different from the frequency or voltage of the data signal SD. In some embodiments, the frequency or voltage of the error passing down signal SWE is different from the frequency or voltage of the passing down signal SW. In some embodiments, when the voltage of the data signal SD is higher than or lower than a voltage threshold, the processor 130 will determine that the abovementioned data signal SD is the error data signal SDE. In some embodiments, when the voltage of the passing down signal SW is higher than or lower than a voltage threshold, the processor 130 will determine that the abovementioned passing down signal SW is the error passing down signal SWE.

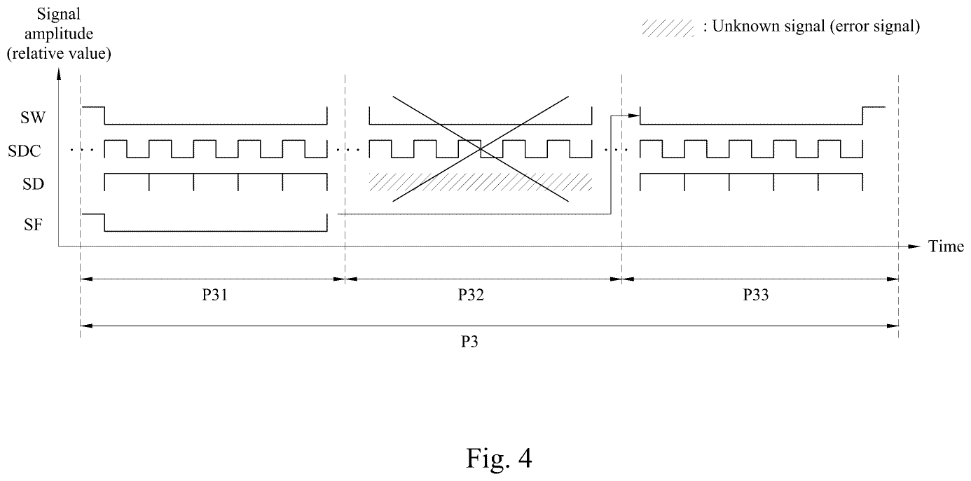

FIG. 4 is a time diagram of a plurality of signals of a chip inspection device in accordance with an embodiment of the present disclosure. As shown in FIG. 4, in some embodiments, the time diagram comprises the passing down signal SW, the data clock signal SDC, the data signal SD, the feedback signal SF, an unknown signal and a period P3. The period P3 comprises sub-periods P31, P32 and P33.

For example, the unknown signal may be the error passing down signal SWE, but the present disclosure is not limited thereto.

In some embodiments, the passing down signal SW, the data clock signal SDC and the unknown signal in the sub-period P32 may be omitted by the processor 130, but the present disclosure is not limited thereto.

In some embodiments, the sub-period P33 may be the result of the unknown signal (e.g., the error passing down signal SWE) in the sub-period P23 being replaced by the feedback signal SF. In this embodiment, the sub-period P33 may be the result of the unknown signal (e.g., the error data signal SDE) in the sub-period P23 being replaced by, converted into or transformed into the data signal SD, but the present disclosure is not limited thereto.

In some embodiments, the passing down signal SW in the sub-period P31 and the passing down signal SW (or the feedback signal SF) in the sub-period P33 each have a pulse length W1.

For example, the passing down signal SW in the sub-period P31 and the passing down signal SW (or the feedback signal SF) in the sub-period P33 each have a high-level signal and a low-level signal, and the pulse length W1 may be the time length of the abovementioned low-level signal, but the present disclosure is not limited thereto.

In some embodiments, the data clock signal SDC in the sub-period P31 and the data clock signal SDC in the sub-period P33 each have a pulse length W2.

For example, the data clock signal SDC in the sub-period P31 and the data clock signal SDC in the sub-period P33 each have a high-level signal and a low-level signal, and the pulse length W2 may be the time length of the abovementioned high-level signal, but the present disclosure is not limited thereto.

In addition, the pulse length W2 may also be the time length of the abovementioned low-level signal, but the present disclosure is not limited thereto.

Please refer to FIG. 1 and FIG. 4 together. In some embodiments, during the period P3, the first chip 110 fails, and the processor 130 of the chip inspection device 100 may reversely transmit the feedback signal SF from the second chip 120 next to the failed first chip 110.

For example, the feedback signal SF may be a chip select signal. The difference between the passing down signal SW and the feedback signal SF is that the passing down signal SW may be transmitted to the second chip 120 along the first wire L1 in the forward direction, and the feedback signal SF may be transmitted to the second chip 120 along the second wire L2 in the reverse direction, but the present disclosure is not limited thereto.

In addition, during the sub-period P32, the first chip 110 fails. During the sub-period P33, the processor 130 outputs the feedback signal SF to the second chip 120 through the second wire L2, and the processor 130 replaces the error passing down signal SWE received by the second chip 120 during the sub-period P23 with the feedback signal SF. Next, during the sub-period P33, the second chip 120 may receive the feedback signal SF and output the data signal SD to the processor 130, but the present disclosure is not limited thereto.

In some embodiments, the sub-period P32 is after the sub-period P31, and the sub-period P33 is after the sub-period P32. In some embodiments, the length of the sub-period P32 is the same as the length of the sub-period P31, and the length of the sub-period P33 is the same as the length of the sub-period P32. In some embodiments, the length of the sub-period P32 is different from the length of the sub-period P31. In some embodiments, the length of the sub-period P33 is different from the length of the sub-period P32.

Please refer to FIGS. 1-4 together. In an embodiment, during the initial period P1, the processor 130 sequentially writes the data signal SD to the first chip 110 and the second chip 120 to perform inspection. During the initial period P1, the processor 130 outputs the passing down signal SW to the first chip 110.

For example, after the chip inspection device 100 is booted, the chip inspection device 100 enters the initial period P1 and the processor 130 enters a micro IC scanning mode, the processor 130 writes the data signal SD to the first chip 110 first, and then the processor 130 writes the data signal SD to the second chip 120, but the present disclosure is not limited thereto.

In addition, the data signal SD may be a signal configured to check whether the first chip 110 and/or the second chip 120 can operate normally, but the present disclosure is not limited thereto.

In this embodiment, during the inspection period P2, the first chip 110 outputs the error data signal SDE to the processor 130 according to the data signal SD.

For example, during the initial period P1, the first chip 110 writes the data signal SD in a data writing mode. When entering the inspection period P2, the first chip 110 may switch to a data outputting mode.

However, if the first chip 110 fails, the first chip 110 cannot output the normal data signal SD to the processor 130. The first chip 110 outputs an unknown signal (e.g. the error data signal SDE) to the processor 130, but the present disclosure is not limited thereto.

In this embodiment, during the inspection period P2, the first chip 110 outputs the error passing down signal SWE to the second chip 120 according to the passing down signal SW.

For example, during the initial period P1, the first chip 110 receives the passing down signal SW. Next, during the inspection period P2, since the first chip 110 fails, the first chip 110 cannot output the normal passing down signal SW. The first chip 110 outputs an unknown signal (e.g. the error passing down signal SWE) to the second chip 120, but the present disclosure is not limited thereto.

In this embodiment, during the inspection period P2, the second chip 120 receives the error passing down signal SWE and outputs the error data signal SDE to the processor 130.

For example, during the inspection period P2, the second chip 120 receives the error passing down signal SWE from the first chip 110. Subsequently, even if the second chip 120 does not fail, the second chip 120 will be unable to output the normal passing down signal SW because it receives the error passing down signal SWE, and the second chip 120 will output an unknown signal (e.g. the error passing down signal SWE), but the present disclosure is not limited thereto.

In addition, during the initial period P1, the second chip 120 writes the data signal SD in the data writing mode. When entering the inspection period P2, the second chip 120 may switch to the data outputting mode. However, since the second chip 120 is affected by the error passing down signal SWE of the first chip 110, the second chip 120 cannot output the normal data signal SD to the processor 130, and the second chip 120 may output an unknown signal (e.g. the error data signal SDE) to the processor 130, but the present disclosure is not limited thereto.

In this embodiment, during the calibration period P3, the processor 130 outputs the feedback signal SF to the second chip 120 according to the error data signal SDE of the first chip 110, and the processor 130 writes the data signal SD to the second chip 120.

For example, during the calibration period P3, the processor 130 may determine that the second chip 120 does not fail and the second chip 120 outputs unknown signals (e.g. the error data signal SDE and/or the error passing down signal SWE) because of being affected by the first chip 110. Therefore, the processor 130 outputs the feedback signal SF to the second chip 120 to replace the error passing down signal SWE received by the second chip 120 from the first chip 110, so that the second chip 120 can subsequently output the normal passing down signal SW, but the present disclosure is not limited thereto.

In addition, during the calibration period P3, the second chip 120 writes the data signal SD in the data writing mode, and the processor 130 may write the data signal SD to the second chip 120, but the present disclosure is not limited thereto.

In this embodiment, during the calibration period P3, the second chip 120 receives the feedback signal SF and the data signal SD, and the second chip 120 outputs the feedback signal SF or the passing down signal SW according to the feedback signal SF. In this embodiment, the inspection period P2 is after the initial period P1, and the calibration period P3 is after the inspection period P2.

For example, during the calibration period P3, the second chip 120 may receive the feedback signal SF output by the processor 130 and the data signal SD output by the processor 130, and the second chip 120 may output the feedback signal SF or the passing down signal SW according to the feedback signal SF, but the present disclosure is not limited thereto.

In some embodiments, the length of the initial period P1 may be 1 frame, the length of the inspection period P2 may be 1 frame, the length of the calibration period P3 may be 1 frame, but the present disclosure is not limited thereto.

In an embodiment, the processor 130 receives the error data signal SDE of the first chip 110 and determines whether the first chip 110 is in a fault state according to the error data signal SDE of the first chip 110.

For example, in general, when the first chip 110 operates normally, the processor 130 writes the data signal SD to the first chip 110, the first chip 110 will output the data signal SD to the processor 130. If the processor 130 writes the data signal SD to the first chip 110, while the first chip 110 outputs an unknown signal (e.g., the error data signal SDE) to the processor 130, the processor 130 may determine whether the first chip 110 is in a fault state according to the error data signal SDE of the first chip 110, but the present disclosure is not limited thereto.

In this embodiment, when the processor 130 receives the error data signal SDE of the first chip 110, the processor 130 determines that the first chip 110 is in the fault state.

For example, when the processor 130 receives the error data signal SDE of the first chip 110, the processor 130 may determine that the first chip 110 is in the fault state, but the present disclosure is not limited thereto.

In an embodiment, when the first chip 110 is in the fault state, the processor 130 outputs the feedback signal SF to the second chip 120.

For example, when the first chip 110 is in the fault state, the signal that the second chip 120 receives from the first chip 110 may be an unknown signal. Therefore, the processor 130 may output the feedback signal SF to the second chip 120 to replace the unknown signal of the first chip, so as to make the second chip 120 operate normally, but the present disclosure is not limited thereto.

In this embodiment, the second chip 120 then receives the feedback signal SF and replaces the error passing down signal SWE with the feedback signal SF according to the feedback signal SF.

For example, the second chip 120 may receive correct signals (e.g., the feedback signal SF) from the processor 130 to maintain normal operation, but the present disclosure is not limited thereto.

In this embodiment, next, the second chip 120 outputs the feedback signal SF or the passing down signal SW according to the feedback signal SF. In this embodiment, the feedback signal SF is the same as the passing down signal SW.

For example, the feedback signal SF and the passing down signal SW may be the same signal, and the second chip 120 may output the feedback signal SF (i.e., the passing down signal SW) according to the feedback signal SF, but the present disclosure is not limited thereto.

In an embodiment, the processor 130 receives the error data signal SDE of the first chip 110 and determines whether a part of the first wire L1 is in a damaged state according to the error data signal SDE of the first chip 110.

For example, the part of the first wire L1 may be the sub-wire L12, and the processor 130 may determine whether the sub-wire L12 is in the damaged state according to the error data signal SDE of the first chip 110, but the present disclosure is not limited thereto.

In this embodiment, when the processor 130 receives the error data signal SDE of the first chip 110, the processor 130 determines that the part of the first wire L1 is in the damaged state. In this embodiment, the part of the first wire L1 is located between the first chip 110 and the second chip 120.

For example, when the processor 130 receives the error data signal SDE of the first chip 110, the processor 130 may determine that the sub-wire L12 is in the damaged state, but the present disclosure is not limited thereto.

In an embodiment, when the part of the first wire L1 is in the damaged state, the processor 130 outputs the feedback signal SF to the second chip 120.

For example, when the sub-wire L12 is in the damaged state, the processor 130 may output the feedback signal SF to the second chip 120, but the present disclosure is not limited thereto.

In this embodiment, the second chip 120 receives the feedback signal SF and replaces the error passing down signal SWE with the feedback signal SF according to the feedback signal SF.

For example, the second chip 120 may receive the feedback signal SF output by the processor 130, so as to replace (or ignore) the error passing down signal SWE output by the first chip 110, but the present disclosure is not limited thereto.

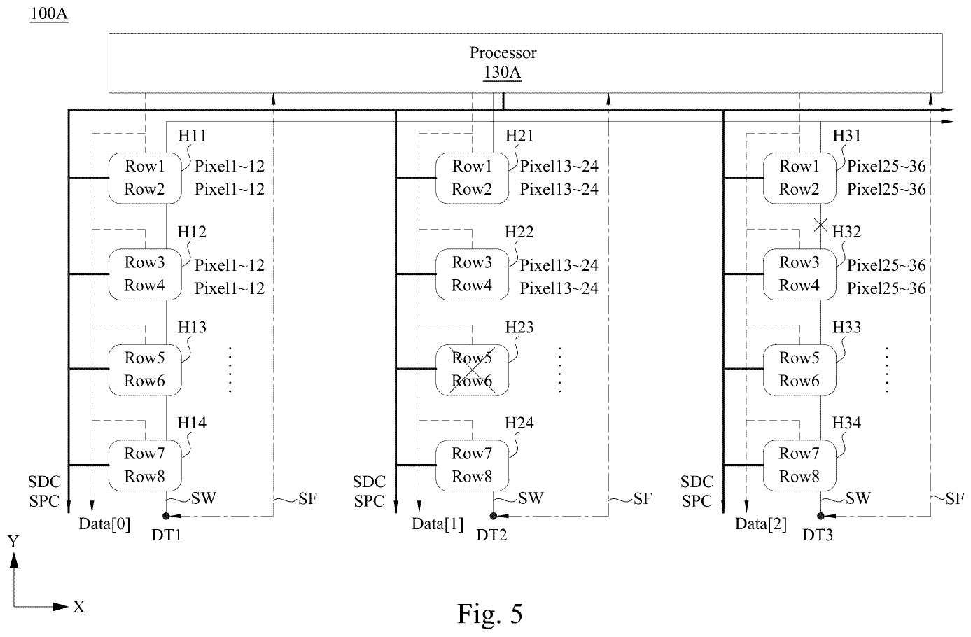

FIG. 5 is a use scenario diagram of a chip inspection device in accordance with an embodiment of the present disclosure. As shown in FIG. 5, in some embodiments, the chip inspection device 100A comprises a processor 130A, chips H11, H12, H13, H14, H21, H22, H23, H24, H31, H32. H33, H34 and nodes DT1, DT2, DT3.

For example, the chip inspection device 100A in FIG. 5 may correspond to the chip inspection device 100 in FIG. 1, the chips H23 and H31 in FIG. 5 may each correspond to the first chip 110 in FIG. 1, the chips H24 and H32 in FIG. 5 may each correspond to the second chip 120 in FIG. 1, and the nodes DT1, DT2 DT3 in FIG. 5 may each correspond to the node DT in FIG. 1, but the present disclosure is not limited thereto.

In some embodiments, the chips H11, H12, H13 and H14 may be arranged along a specific direction (e.g., Y axis). In some embodiments, the chips H21, H22, H23 and H24 may be arranged along a specific direction (e.g., Y axis). In some embodiments, the chips H31, H32, H33 and H34 may be arranged along a specific direction (e.g., Y axis).

In some embodiments, the processor 130A may be coupled to the chips H11, H12, H13, H14 and the node DT1 through a first wire, and the processor 130A may be coupled to the chips H21, H22, H23, H24 and the node DT2 through a second wire. In some embodiments, the processor 130A may be coupled to the chips H21, H22, H23, H24 and the node DT2 through the first wire, and the processor 130A may be coupled to the node DT2 through the second wire. In some embodiments, the processor 130A may be coupled to the chips H31, H32, H33, H34 and the node DT3 through the first wire, and the processor 130A may be coupled to the node DT3 through the second wire.

For example, the abovementioned first wire may correspond to the first wire L1 in FIG. 1, the abovementioned second wire may correspond to the second wire L2 in FIG. 1, the abovementioned first wire may transmit the passing down signal SW, and the abovementioned second wire may transmit the feedback signal SF, but the present disclosure is not limited thereto.

In some embodiments, the processor 130A outputs the data clock signal SDC and the pulse clock signal SPC to the chips H11, H12, H13, H14, H21, H22, H23, H24, H31, H32. H33 and H34.

In some embodiments, the processor 130A outputs the data signal Data [0] to the chips H11, H12, H13 and H14 sequentially. In some embodiments, the processor 130A outputs the data signal Data [1] to the chips H21, H22, H23 and H24 sequentially. In some embodiments, the processor 130A outputs the data signal Data [2] to the chips H31, H32, H33 and H34 sequentially.

For example, the data signals Data [0], Data [1] and Data [2] may have a preceding and following relationship with each other. The data signals Data [0], Data [1] and Data [2] in FIG. 5 may each correspond to the data signal SD in FIG. 1, but the present disclosure is not limited thereto.

In some embodiments, the rows 1-8 in FIG. 5 may represent the first to eighth rows along a specific direction (e.g., X axis), but the present disclosure is not limited thereto.

In some embodiments, the chip H11 may output signals to the pixels 1-12of the first row and the pixels 1-12 of the second row, the chip H12 may output signals to the pixels 1-12 of the third row and the pixels 1-12 of the fourth row, the chip H13 may output signals to the pixels 1-12 of the fifth row and the pixels 1-12of the sixth row, and the chip H14 may output signals to the pixels 1-12 of the seventh row and the pixels 1-12 of the eighth row.

In some embodiments, the chip H21 may output signals to the pixels 13-24of the first row and the pixels 13-24 of the second row, the chip H22 may output signals to the pixels 13-24 of the third row and the pixels 13-24 of the fourth row, the chip H23 may output signals to the pixels 13-24 of the fifth row and the pixels 13-24 of the sixth row, and the chip H24 may output signals to the pixels 13-24 of the seventh row and the pixels 13-24 of the eighth row.

In some embodiments, the chip H31 may output signals to the pixels 25-36of the first row and the pixels 25-36 of the second row, the chip H32 may output signals to the pixels 25-36 of the third row and the pixels 25-36 of the fourth row, the chip H33 may output signals to the pixels 25-36 of the fifth row and the pixels 25-36 of the sixth row, and the chip H34 may output signals to the pixels 25-36 of the seventh row and the pixels 25-36 of the eighth row.

In some embodiments, the chip inspection device 100A is used in light-emitting diode panels. When the chip H23 fails, the pixels 13-24 of the fifth to eighth rows driven by the chips H23 and H24 cannot light up, thereby forming a dark area on the panel. If there are still multiple chips subsequently coupled to the chip H24, these chips will be affected by the chip H23 and unable to drive the corresponding pixels, thereby forming a dark area on the panel in a similar way.

However, the chip inspection device 100A of the present disclosure can output the feedback signal SF to the chip H24 through the second wire by the processor 130A, so that the chip H24 and the chips subsequently coupled to the chip H24 can operate normally, thereby limiting the dark area on the panel to the area that cannot be lit corresponding to the failure of the chip H23. Furthermore, the dark area (or the dark line) on the panel caused by the failure of the chip H23 has little impact on the user, and the user can still use the panel normally to meet daily needs.

For general technology, the failure of a single component (e.g., the chip H23 or the wires between chips) may cause most areas of the panel (probably 30% to 80% of the area) to be unable to light up and display images. Users often have no choice but to discard the panel or send it in for repair if it becomes unusable. However, the chip inspection device 100A of the present disclosure can avoid the situation that the failure of a single component (e.g., the chip H23 or the wires between chips) causes the entire panel to be unable to use, thereby achieving instant repair and extending panel life.

In some embodiments, when the wire between the chips H31 and H32 is disconnected, the pixels 25-36 of the third to eighth rows driven by the chips H32, H33 and H34 cannot light up, thereby forming a dark area on the panel. If there are still multiple chips subsequently coupled to the chip H34, these chips will be affected by the disconnection of the wire between the chips H31, H32 and unable to drive the corresponding pixels, thereby forming a dark area on the panel in a similar way.

However, the chip inspection device 100A of the present disclosure can output the feedback signal SF to the chip H32 through the second wire by the processor 130A, so that the chips H32, H33, H34 and the chips subsequently coupled to the chip H34 can operate normally, and the user can still use the panel normally to meet daily needs.

In some embodiments, the nodes DT1, DT2 and DT3 may be located at the bottom of the panel (i.e., the edge of the panel) or the bottom of the light-emitting area of the panel (i.e., the edge of the light-emitting area of the panel), but the present disclosure is not limited thereto.

In some embodiments, the processor 130A outputs the passing down signal SW through a first wire. In some embodiments, the processor 130A outputs the feedback signal SF through a second wire. In some embodiments, the processor 130A outputs the data clock signal SDC and the pulse clock signal SPC through a third wire. In some embodiments, the processor 130A outputs the data signals Data [0], Data [1] and Data [2] through a fourth wire. In some embodiments, the first wire, the third wire and the fourth wire may be the same wire. In some embodiments, the first wire, the second wire, the third wire and the fourth wire may be different wires.

In some embodiments, the operations of the chip inspection device 100A in FIG. 5 are similar to the operations of the chip inspection device 100 in FIG. 1, but the present disclosure is not limited thereto.

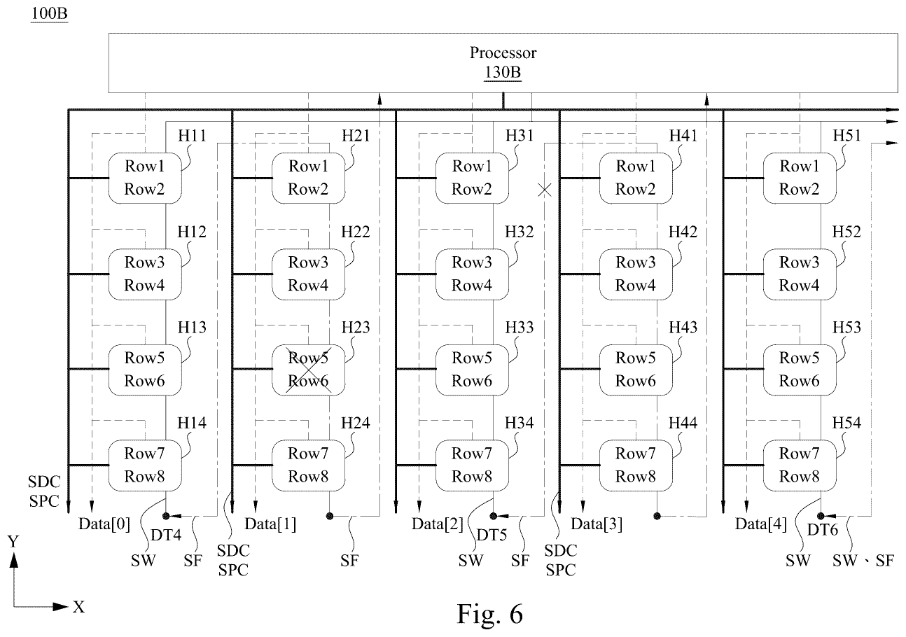

FIG. 6 is a use scenario diagram of a chip inspection device in accordance with an embodiment of the present disclosure. As shown in FIG. 6, in some embodiments, the chip inspection device 100B comprises a processor 130B, chips H11, H12, H13, H14, H21, H22, H23, H24, H31, H32, H33, H34, H41, H42, H43, H44, H51, H52, H53, H54 and nodes DT4, DT5, DT6.

For example, the structure and operations of the chip inspection device 100B in FIG. 6 are similar to the structure and operations of the chip inspection device 100A in FIG. 5, but the present disclosure is not limited thereto.

It should be noted that the processor 130B and the chips H11, H12, H13, H14 may be coupled to each other through a first wire, and the chips H14, H21, H22, H23, H24 may be coupled to each other through a second wire.

In addition, the processor 130B may output the passing down signal to the chips H11, H12, H13, H14, H21, H22, H23 and H24 sequentially through the first wire and the second wire, and the processor 130B may output the feedback signal to the chips H24, H23, H22, H21, H14, H13, H12 and H11 sequentially through the second wire and the first wire.

For example, the first wire in FIG. 6 may correspond to the first wire L1 in FIG. 1, the second wire in FIG. 6 may correspond to the second wire L2 in FIG. 1, the passing down signal in FIG. 6 may correspond to the passing down signal SW in FIG. 1, and the feedback signal in FIG. 6 may correspond to the feedback signal SF in FIG. 1, but the present disclosure is not limited thereto.

In some embodiments, the chips H11, H12, H13, H14, H21, H22, H23, H24, H31, H32. H33 and H34 in FIG. 6 may correspond to the chips H11, H12, H13, H14, H21, H22, H23, H24, H31, H32, H33 and H34 in FIG. 5.

In some embodiments, the chip H41 may output signals to the pixels 37-48 of the first row and the pixels 37-48 of the second row, the chip H42 may output signals to the pixels 37-48 of the third row and the pixels 37-48 of the fourth row, the chip H43 may output signals to the pixels 37-48 of the fifth row and the pixels 37-48 of the sixth row, and the chip H44 may output signals to the pixels 37-48 of the seventh row and the pixels 37-48 of the eighth row.

In some embodiments, the chip H51 may output signals to the pixels 49-60 of the first row and the pixels 49-60 of the second row, the chip H52 may output signals to the pixels 49-60 of the third row and the pixels 49-60 of the fourth row, the chip H53 may output signals to the pixels 49-60 of the fifth row and the pixels 49-60 of the sixth row, and the chip H54 may output signals to the pixels 49-60 of the seventh row and the pixels 49-60 of the eighth row.

In some embodiments, compared with the chip inspection device 100A in FIG. 5 that can connect different rows of chips together, the chip inspection device 100B in FIG. 6 can effectively reduce the number of pins required by the processor 130B.

In some embodiments, the chip inspection device 100B in FIG. 6 may have the following features: (1) the passing down signal of the processor 130B can form a signal loop through the first wire and the second wire; (2) this signal loop can transmit signals in both directions, for example, transmitting the passing down signal in the forward direction and transmitting the feedback signal in the reverse direction; (3) the processor 130B may have a mechanism to scan multiple chips and inspect the failure of these chips.

In some embodiments, the chip inspection device 100B is used in light-emitting diode panels. When the chip H23 fails, the pixels 13-24 of the fifth to eighth rows driven by the chips H23 and H24 cannot light up, thereby forming a dark area on the panel. If there are still multiple chips subsequently coupled to the chip H24, these chips will be affected by the chip H23 and unable to drive the corresponding pixels, thereby forming a dark area on the panel in a similar way.

However, the chip inspection device 100B of the present disclosure can output the feedback signal SF to the chip H24 through the second wire by the processor 130B, so that the chip H24 and the chips subsequently coupled to the chip H24 can operate normally, thereby limiting the dark area on the panel to the area that cannot be lit corresponding to the failure of the chip H23. Furthermore, the dark area (or the dark line) on the panel caused by the failure of the chip H23 has little impact on the user, and the user can still use the panel normally to meet daily needs.

In some embodiments, when the wire between the chips H34 and H41 is disconnected, the pixels 37-48 of the first to eighth rows driven by the chips H41, H42, H43 and H44 cannot light up, thereby forming a dark area on the panel. If there are still multiple chips subsequently coupled to the chip H44, these chips will be affected by the disconnection of the wire between the chips H34, H41 and unable to drive the corresponding pixels, thereby forming a dark area on the panel in a similar way.

However, the chip inspection device 100B of the present disclosure can output the feedback signal SF to the chip H41 through the second wire by the processor 130B, so that the chips H41, H42, H43, H44 and the chips subsequently coupled to the chip H44 can operate normally, and the user can still use the panel normally to meet daily needs.

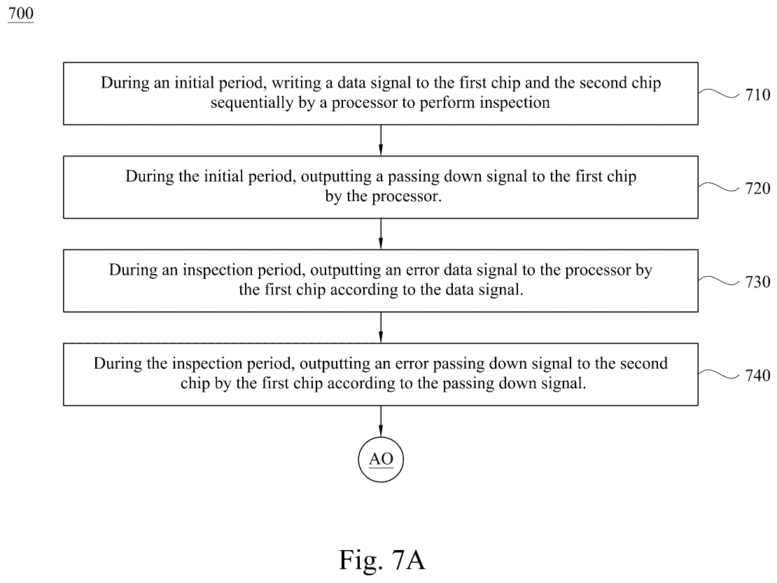

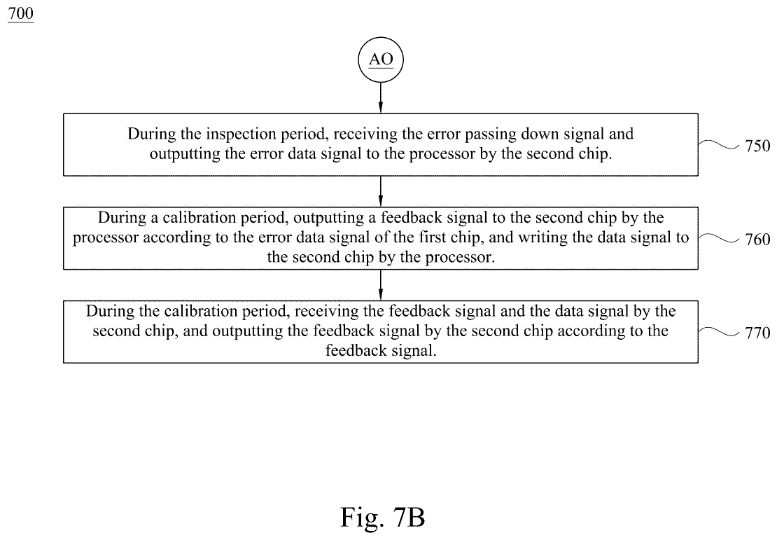

FIG. 7A is a flowchart of a chip inspection method in accordance with an embodiment of the present disclosure. FIG. 7B is a flowchart of a chip inspection method in accordance with an embodiment of the present disclosure. As shown in FIG. 7A and FIG. 7B, in an embodiment, the chip inspection method 700 comprises steps 710, 720, 730, 740, 750, 760 and 770, and the detailed description of steps 710, 720, 730, 740, 750, 760 and 770 will be described in following paragraphs.

In step 710, during an initial period, writing a data signal to a first chip and a second chip sequentially by a processor to perform inspection.

Please refer to FIGS. 1-4, FIG. 7A and FIG. 7B together. In some embodiments, during the initial period P1, the data signal SD may be written to the first chip 110 and the second chip 120 sequentially by the processor 130 to perform inspection.

For example, the operations of the chip inspection method 700 in FIG. 7A and FIG. 7B are similar to the operations of the chip inspection device 100 in FIG. 1. For the sake of brevity, the detailed description will not be repeated herein.

In step 720, during the initial period, outputting a passing down signal to the first chip by the processor.

Please refer to FIGS. 1-4, FIG. 7A and FIG. 7B together. In some embodiments, during the initial period P1, the passing down signal SW may be output to the first chip 110 by the processor 130.

For example, the operations of the chip inspection method 700 in FIG. 7A and FIG. 7B are similar to the operations of the chip inspection device 100 in FIG. 1. For the sake of brevity, the detailed description will not be repeated herein.

In step 730, during an inspection period, outputting an error data signal to the processor by the first chip according to the data signal.

Please refer to FIGS. 1-4, FIG. 7A and FIG. 7B together. In some embodiments, during the inspection period P2, the error data signal SDE may be output to the processor 130 by the first chip 110 according to the data signal SD.

For example, the operations of the chip inspection method 700 in FIG. 7A and FIG. 7B are similar to the operations of the chip inspection device 100 in FIG. 1. For the sake of brevity, the detailed description will not be repeated herein.

In step 740, during the inspection period, outputting an error passing down signal to the second chip by the first chip according to the passing down signal.

Please refer to FIGS. 1-4, FIG. 7A and FIG. 7B together. In some embodiments, during the inspection period P2, the error passing down signal SWE may be output to the second chip 120 by the first chip 110 according to the passing down signal SW.

For example, the operations of the chip inspection method 700 in FIG. 7A and FIG. 7B are similar to the operations of the chip inspection device 100 in FIG. 1. For the sake of brevity, the detailed description will not be repeated herein.

In step 750, during the inspection period, receiving the error passing down signal and outputting the error data signal to the processor by the second chip.

Please refer to FIGS. 1-4, FIG. 7A and FIG. 7B together. In some embodiments, during the inspection period P2, the error passing down signal SWE may be received by the second chip 120, and the error data signal SDE may be output to the processor 130 by the second chip 120.

For example, the operations of the chip inspection method 700 in FIG. 7A and FIG. 7B are similar to the operations of the chip inspection device 100 in FIG. 1. For the sake of brevity, the detailed description will not be repeated herein.

In step 760, during a calibration period, outputting a feedback signal to the second chip by the processor according to the error data signal of the first chip, and writing the data signal to the second chip by the processor.

Please refer to FIGS. 1-4, FIG. 7A and FIG. 7B together. In some embodiments, during the calibration period P3, the feedback signal SF may be output to the second chip 120 by the processor 130 according to the error data signal SDE of the first chip 110, and the data signal SD may be written to the second chip 120 by the processor 130.

For example, the operations of the chip inspection method 700 in FIG. 7A and FIG. 7B are similar to the operations of the chip inspection device 100 in FIG. 1. For the sake of brevity, the detailed description will not be repeated herein.

In step 770, during the calibration period, receiving the feedback signal and the data signal by the second chip, and outputting the feedback signal by the second chip according to the feedback signal.

Please refer to FIGS. 1-4, FIG. 7A and FIG. 7B together. In some embodiments, during the calibration period P3, the feedback signal SF and the data signal SD may be received by the second chip 120, and the feedback signal SF may be output by the second chip 120 according to the feedback signal SF.

For example, the operations of the chip inspection method 700 in FIG. 7A and FIG. 7B are similar to the operations of the chip inspection device 100 in FIG. 1. For the sake of brevity, the detailed description will not be repeated herein.

In some embodiments, there is step AO between step 740 and step 750. This step AO is only used to connect step 740 and step 750 and has no special significance, and thus can be ignored, but the present disclosure is not limited thereto.

In some embodiments, there may be any one or more steps related to chip inspections between steps 710, 720, 730, 740, 750, 760 and 770, but the present disclosure is not limited thereto.

In some embodiments, there may be any one or more steps related to chip inspections before step 710 or after step 770, but the present disclosure is not limited thereto.

In some embodiments, the order of steps 710, 720, 730, 740, 750, 760 and 770 can be arranged in any order, but the present disclosure is not limited thereto.

Please refer to FIGS. 1-4, FIG. 7A and FIG. 7B together. In an embodiment, the chip inspection method 700 further comprises: receiving the error data signal SDE of the first chip 110 and determining whether the first chip 110 is in the fault state according to the error data signal SDE of the first chip 110 by the processor 130; and determining that the first chip 110 is in the fault state by the processor 130 when the processor 130 receives the error data signal SDE of the first chip 110.

For example, the operations of the chip inspection method 700 in FIG. 7A and FIG. 7B are similar to the operations of the chip inspection device 100 in FIG. 1. For the sake of brevity, the detailed description will not be repeated herein.

In an embodiment, the chip inspection method 700 further comprises: outputting the feedback signal SF to the second chip 120 by the processor 130 when the first chip 110 is in the fault state; receiving the feedback signal SF and replacing the error passing down signal SWE with the feedback signal SF according to the feedback signal SF by the second chip 120; and outputting the feedback signal SF or the passing down signal SW according to the feedback signal SF by the second chip 120. In this embodiment, the feedback signal is the same as the passing down signal.

For example, the operations of the chip inspection method 700 in FIG. 7A and FIG. 7B are similar to the operations of the chip inspection device 100 in FIG. 1. For the sake of brevity, the detailed description will not be repeated herein.

In an embodiment, the chip inspection method 700 further comprises: receiving the error data signal SDE of the first chip 110 and determining whether a part of the first wire L1 is in the damaged state according to the error data signal SDE of the first chip 110 by the processor 130; and determining that the part of the first wire L1 is in the damaged state by the processor 130 when the processor 130 receives the error data signal SDE of the first chip 110. In this embodiment, the part of the first wire L1 is located between the first chip 110 and the second chip 120.

For example, the operations of the chip inspection method 700 in FIG. 7A and FIG. 7B are similar to the operations of the chip inspection device 100 in FIG. 1. For the sake of brevity, the detailed description will not be repeated herein.

It can be seen from the abovementioned embodiments of the present disclosure that the embodiments of the present disclosure have the following advantages. The chip inspection device and the chip inspection method shown in the embodiment of the present disclosure use a processor to output feedback signals to the chips, so as to achieve the effect of normal operations of the chips.

Although the above embodiments disclose specific examples of the present disclosure, they are not intended to limit the present disclosure. Those skilled in the art can make various changes and modifications without departing from the scope and spirit of the present disclosure. Therefore, the scope of the present disclosure is subject to the scope of the following claims.

What is claimed is:

1. A chip inspection device, comprising:
a first chip;
a second chip, coupled to the first chip; and
a processor, coupled to the first chip and the second chip;
wherein during an initial period, the processor sequentially writes a data signal to the first chip and the second chip to perform inspection;
wherein during the initial period, the processor outputs a passing down signal to the first chip;
wherein during an inspection period, the first chip outputs an error data signal to the processor according to the data signal;
wherein during the inspection period, the first chip outputs an error passing down signal to the second chip according to the passing down signal;
wherein during the inspection period, the second chip receives the error passing down signal and outputs the error data signal to the processor;
wherein during a calibration period, the processor outputs a feedback signal to the second chip according to the error data signal of the first chip, and the processor writes the data signal to the second chip;
wherein during the calibration period, the second chip receives the feedback signal and the data signal, and the second chip outputs the feedback signal or the passing down signal according to the feedback signal; and
wherein the inspection period is after the initial period, and the calibration period is after the inspection period.

2. The chip inspection device of claim 1, wherein
the processor receives the error data signal of the first chip and determines whether the first chip is in a fault state according to the error data signal of the first chip; and
when the processor receives the error data signal of the first chip, the processor determines that the first chip is in the fault state.

3. The chip inspection device of claim 2, wherein
when the first chip is in the fault state, the processor outputs the feedback signal to the second chip;
wherein the second chip receives the feedback signal and replaces the error passing down signal with the feedback signal according to the feedback signal;
wherein the second chip outputs the feedback signal or the passing down signal according to the feedback signal; and
wherein the feedback signal is the same as the passing down signal.

4. The chip inspection device of claim 1, wherein the processor is coupled to the first chip through a first wire;
wherein the first chip is coupled to the second chip through the first wire; and
wherein the first wire is configured to transmit the passing down signal.

5. The chip inspection device of claim 4, wherein
the second chip is coupled to a node through the first wire;
wherein the node is coupled to the processor through a second wire; and
wherein the second wire is configured to transmit the feedback signal.

6. The chip inspection device of claim 5, wherein
the processor receives the error data signal of the first chip and determines whether a part of the first wire is in a damaged state according to the error data signal of the first chip;
when the processor receives the error data signal of the first chip, the processor determines that the part of the first wire is in the damaged state; and
wherein the part of the first wire is located between the first chip and the second chip.

7. The chip inspection device of claim 6, wherein
when the part of the first wire is in the damaged state, the processor outputs the feedback signal to the second chip; and
wherein the second chip receives the feedback signal and replaces the error passing down signal with the feedback signal according to the feedback signal.

8. A chip inspection method, comprising:
during an initial period, writing a data signal to a first chip and a second chip sequentially by a processor to perform inspection;
during the initial period, outputting a passing down signal to the first chip by the processor;
during an inspection period, outputting an error data signal to the processor by the first chip according to the data signal;
during the inspection period, outputting an error passing down signal to the second chip by the first chip according to the passing down signal;
during the inspection period, receiving the error passing down signal and outputting the error data signal to the processor by the second chip;
during a calibration period, outputting a feedback signal to the second chip by the processor according to the error data signal of the first chip, and writing the data signal to the second chip by the processor; and
during the calibration period, receiving the feedback signal and the data signal by the second chip, and outputting the feedback signal by the second chip according to the feedback signal.

9. The chip inspection method of claim 8, further comprising:
receiving the error data signal of the first chip and determining whether the first chip is in a fault state according to the error data signal of the first chip by the processor; and
determining that the first chip is in the fault state by the processor when the processor receives the error data signal of the first chip.

10. The chip inspection method of claim 9, further comprising:
outputting the feedback signal to the second chip by the processor when the first chip is in the fault state;
receiving the feedback signal and replacing the error passing down signal with the feedback signal according to the feedback signal by the second chip; and
outputting the feedback signal or the passing down signal according to the feedback signal by the second chip;
wherein the feedback signal is the same as the passing down signal.

11. The chip inspection method of claim 8, wherein
the processor is coupled to the first chip through a first wire;
wherein the first chip is coupled to the second chip through the first wire; and
wherein the first wire is configured to transmit the passing down signal.

12. The chip inspection method of claim 11, wherein
the second chip is coupled to a node through the first wire;
wherein the node is coupled to the processor through a second wire; and
wherein the second wire is configured to transmit the feedback signal.

13. The chip inspection method of claim 8, further comprising:
receiving the error data signal of the first chip and determining whether a part of a first wire is in a damaged state according to the error data signal of the first chip by the processor; and
determining that the part of the first wire is in the damaged state by the processor when the processor receives the error data signal of the first chip;
wherein the part of the first wire is located between the first chip and the second chip.

14. The chip inspection method of claim 13, further comprising:
outputting the feedback signal to the second chip by the processor when the part of the first wire is in the damaged state; and
receiving the feedback signal and replacing the error passing down signal with the feedback signal according to the feedback signal by the second chip.

15. A chip inspection device, comprising:
a first chip;
a second chip, coupled to the first chip; and
a processor, coupled to the first chip and the second chip;
wherein during an initial period, the processor sequentially writes a data signal to the first chip and the second chip to perform inspection;
wherein during an inspection period, the first chip outputs an error data signal to the processor according to the data signal;
wherein during a calibration period, the processor outputs a feedback signal to the second chip according to the error data signal of the first chip, and the processor writes the data signal to the second chip;
wherein during the calibration period, the second chip receives the feedback signal and the data signal, and the second chip outputs according to the feedback signal; and
wherein the inspection period is after the initial period, and the calibration period is after the inspection period.

16. The chip inspection device of claim 15, wherein
during the initial period, the processor outputs a passing down signal to the first chip;
wherein during the inspection period, the first chip outputs an error passing down signal to the second chip according to the passing down signal;
wherein during the inspection period, the second chip receives the error passing down signal and outputs the error data signal to the processor; and
wherein during the calibration period, the second chip outputs the feedback signal or the passing down signal according to the feedback signal.

17. The chip inspection device of claim 16, wherein
the processor receives the error data signal of the first chip and determines whether the first chip is in a fault state according to the error data signal of the first chip;
when the processor receives the error data signal of the first chip, the processor determines that the first chip is in the fault state;
when the first chip is in the fault state, the processor outputs the feedback signal to the second chip;
wherein the second chip receives the feedback signal and replaces the error passing down signal with the feedback signal according to the feedback signal;
wherein the second chip outputs the feedback signal or the passing down signal according to the feedback signal; and
wherein the feedback signal is the same as the passing down signal.

18. The chip inspection device of claim 16, wherein
the processor is coupled to the first chip through a first wire;
wherein the first chip is coupled to the second chip through the first wire;
wherein the second chip is coupled to a node through the first wire;
wherein the first wire is configured to transmit the passing down signal;
wherein the node is coupled to the processor through a second wire; and
wherein the second wire is configured to transmit the feedback signal.

19. The chip inspection device of claim 18, wherein
the processor receives the error data signal of the first chip and determines whether a part of the first wire is in a damaged state according to the error data signal of the first chip;
when the processor receives the error data signal of the first chip, the processor determines that the part of the first wire is in the damaged state; and
wherein the part of the first wire is located between the first chip and the second chip.

20. The chip inspection device of claim 19, wherein
when the part of the first wire is in the damaged state, the processor outputs the feedback signal to the second chip; and
wherein the second chip receives the feedback signal and replaces the error passing down signal with the feedback signal according to the feedback signal.
